(19) United States
(12) Patent Application Publication
(10) Pub. No.: US 2011/0304335 A1
(43) Pub. Date: Dec. 15, 2011

(54) Method For Determining The Radiation Attenuation Of A Local Coil

(75) Inventor: Matthias Fenchel, Erlangen (DE)

(73) Assignee: SIEMENS AKTIENGESELLSCHAFT, Munich (DE)

(21) Appl. No.: 13/156,464

(22) Filed: Jun. 9, 2011

(30) Foreign Application Priority Data
Jun. 11, 2010 (DE) 10 2010 023 545.8

(51) Int. Cl. G01R 33/44

(52) U.S. Cl. 324/318

(57) ABSTRACT

A method is disclosed for determining radiation attenuation by a local coil in a tomography scanner of a magnetic resonance-positron emission tomography system. In at least one embodiment of the method, arrangement-dependent radiation attenuation, which depends on a coil-arrangement parameter record, is set for the local coil. Raw radiation data of an examination object is acquired with the aid of the MR-PET system and a plurality of images of the examination object are determined from the raw radiation data. In the process, each image is determined with a different coil-arrangement parameter record, taking into account the arrangement-dependent radiation attenuation. Each image is assigned a cost value, which corresponds to a measure of artifacts in the image. The radiation attenuation by the local coil is determined from the arrangement-dependent radiation attenuation and the coil-arrangement parameter record, which is associated with the optimized cost value, by determining an optimized cost value.

### PRIORITY STATEMENT

The present application hereby claims priority under 35 U.S.C. §119 on German patent application number DE 10 2010 023 545.8 filed Jun. 11, 2010, the entire contents of which are hereby incorporated herein by reference.

### FIELD

At least one embodiment of the present invention generally relates to a method for determining radiation attenuation by a local coil in a tomography scanner of a magnetic resonance-positron emission tomography hybrid system, and/or to a corresponding device and/or a corresponding magnetic resonance-positron emission tomography hybrid system. In particular, the method of at least one embodiment automatically determines an arrangement of the local coil in the tomography scanner.

### BACKGROUND

It is complicated to determine an attenuation correction of radiation data for positron emission tomography on the basis of a magnetic resonance examination in magnetic resonance-positron emission tomography hybrid systems (MR-PET hybrid systems) because local coils, which are used to receive the magnetic resonance signals from the examination object (e.g. a human body), are not visible in the conventional clinical magnetic resonance examination techniques. However, these local coils have a significant influence on the radiation data because the local coils themselves bring about radiation attenuation.

In general, a structure and shape of these coils is known, or can be determined by a separate measurement. By way of example, the attenuation can be determined in a separate method. Moreover, the positions of the local coils are usually known at least approximately. However, it often is the case that the position and the alignment cannot be determined with the required accuracy, particularly in the case of coils that are not fixed in space. If these arrangement parameters are incorrect or not sufficiently accurate, severe errors, so-called artifacts, may occur in the calculated positron emission tomography images. Streak-like artifacts in particular, in which neighboring slices have different intensities, occur as a result of imprecisely determined arrangement parameters for the local coils. FIGS. 3 and 5 show positron emission tomography recordings with such streak-like artifacts. These artifacts can contribute to it not being possible to use the generated images in a clinical context.

Hence the prior art has disclosed various methods for reducing or avoiding impairment of positron emission tomography recordings by local coils. By way of example, the attenuation and position of a local coil may be determined in a separate method. However, this requires an additional measurement and may, under certain circumstances, not be accurate enough, particularly in the case of flexibly positionable local coils. Furthermore, it is possible to use local coils that are largely transparent to radiation of 511 keV photons in order to avoid an attenuation of the radiation in the case of a positron emission tomography recording. However, this is not possible for all types of coils. Furthermore, it is possible to use markings on the coils, which markings are visible either in a positron emission tomography recording or in a magnetic resonance recording. However, markings that are visible in a positron emission tomography recording cause additional radiation. Markings that are visible in magnetic resonance recordings can falsify the image as a result of possibly being convoluted in, even if they are arranged outside of the field of view. A further option consists of using special magnetic resonance sequences in order to measure the positions and arrangements of the coils. However, this increases the measurement time and, moreover, it is questionable whether this can achieve a sufficient position-determination accuracy. Finally, it is possible to use a maximum likelihood optimization reconstruction in order to determine the position of a local coil, as described in, for example, US 2010/0074501 A1. However, this requires raw PET data and considerable computational power. Moreover, it is questionable whether the method can achieve the required accuracy.

### SUMMARY

In at least one embodiment of the present invention, a determination of the radiation attenuation is made by a local coil in a tomography scanner as precisely as possible. Moreover, at least one embodiment of the method should be able to be carried out as quickly as possible and require as few additional measurements as possible.

According to at least one embodiment of the present invention, a method for determining radiation attenuation by a local coil is disclosed; a device for a magnetic resonance-positron emission tomography system is disclosed; a magnetic resonance-positron emission tomography system is disclosed; a computer program product is disclosed; and an electronically readable data medium is disclosed. The dependent claims define preferred and advantageous embodiments of the invention.

According to at least one embodiment of the present invention, provision is made for a method for determining radiation attenuation by a local coil in a tomography scanner of a magnetic resonance-positron emission tomography system. In at least one embodiment of the method, arrangement-dependent radiation attenuation by the local coil arranged in the tomography scanner is set. The arrangement-dependent radiation attenuation by the local coil depends on a coil-arrangement parameter record, which describes an arrangement of the coil in the tomography scanner. By way of example, the coil-arrangement parameter record may comprise a plurality of parameters, which describe a position and an alignment of the local coil.

By way of example, the coil-arrangement parameter record may comprise three parameters to describe the position of the local coil in the three spatial directions and three further parameters for describing the alignment of the local coil in the three spatial directions. The arrangement-dependent radiation attenuation then, as a function of the coil-arrangement parameter record, supplies one or more radiation attenuation values for a local coil arranged in the tomography scanner as per the coil-arrangement parameter record. By way of example, such arrangement-dependent radiation attenuation can be determined once for a local coil, possibly in combination with a particular tomography scanner, and can then be used for all subsequent positron emission tomography recordings. Raw radiation data of an examination object, which has a positron emission source and is arranged in the tomography scanner, is then acquired automatically in a next step of method with the aid of the positron emission tomography system.

By way of example, the examination object can be a patient, who was administered a radiopharmaceutical before the examination. A plurality of images of the examination object are then determined automatically from the acquired raw radiation data, wherein each image is determined, taking into account the arrangement-dependent radiation attenuation by the local coil, by a coil-arrangement parameter record associated with the image.

Here a different coil-arrangement parameter record is associated with each image. By way of example, starting from a roughly estimated arrangement of the local coil, these different coil-arrangement parameter records can be determined by varying the coil-arrangement parameter record within a predetermined range. Then, a so-called cost value is assigned to each of the automatically determined images. The cost value for an image corresponds to a measure of artifacts in the image. By way of example, the cost value can be assigned to an image by a statistical analysis of intensity values in the image. The image with the at least comparatively best cost value is then automatically determined to be the image in which the radiation attenuation by the local coil is taken into account in the most accurate fashion. Accordingly, the radiation attenuation by the local coil is then calculated from the arrangement-dependent radiation attenuation with the coil-arrangement parameter record of precisely that image that has the optimized cost value.

Since the optimization of determining the arrangement of the local coil or determining the radiation attenuation by the local coil is based on precisely one acquired raw radiation data record and a plurality of images determined therefrom, there is no need for additional positron emission tomography recordings, as a result of which the method can be carried out quickly. Since the position of the local coil is not measured directly, but, instead, an effect of a falsely assumed arrangement is reduced or completely eliminated in the image data by an optimization, it is possible to achieve a very high accuracy and quality in the resulting positron emission tomography recordings.

According to one embodiment, the cost value is formed from a plurality of cost-value components, which respectively evaluate one sub-region of the image. A change in an intensity value of a pixel in the image with respect to intensity values of respectively neighboring pixels determines the cost-value component for each sub-region. The streak-like artifacts cause additional local changes in the intensity values in the image. The more artifacts are present in an image, the higher the cost value consequently becomes for these sub-regions and hence for the entire image. By contrast, piecewise constant intensity values lead to a reduction in the cost value. Hence the cost value for an image can be determined in a simple fashion by comparing intensity values in the image. This allows a fast determination of the cost value for an image. An example for such a determination of cost values is a determination of a total variation of intensity values of pixels in the image. Here, for each pixel, a deviation in the intensity is determined from pixels within a predefined neighborhood of the pixel. By way of example, in the case of three-dimensional images, the predetermined neighborhood can comprise the closest 6, 18, or 26 pixels, which lie on the faces, edges, and/or corners of a cube surrounding the pixel.

According to a further embodiment, the coil-arrangement parameters are determined iteratively with the aid of an optimization method, e.g. a gradient descent method, as a function of the cost values of previously determined images and the coil-arrangement parameters thereof. The gradient descent method can be used to find at least local minima for the cost values in a targeted fashion by calculating only a few images. This can accelerate the entire method.

Furthermore, according to at least one embodiment of the present invention, provision is made for a device for a magnetic resonance-positron emission tomography system for determining radiation attenuation by a local coil in a tomography scanner of the magnetic resonance-positron emission tomography system. The device comprises a control unit for actuating a positron emission detector in the tomography scanner and an image-calculation unit for receiving raw radiation data acquired by the positron emission detector and for reconstructing image data from the raw radiation data. The device is able to set arrangement-dependent radiation attenuation by a local coil arranged in the tomography scanner. The arrangement-dependent radiation attenuation depends on a coil-arrangement parameter record, which defines an arrangement of the local coil in the tomography scanner. Furthermore, the device is able to acquire raw radiation data from an examination object, which has a positron emission source, with the aid of the positron emission tomography system, while the local coil and the examination object are arranged in the tomography scanner. The device then determines a plurality of images of the examination object from the raw radiation data. Each image is determined taking into account the arrangement-dependent radiation attenuation by the local coil for a coil-arrangement parameter record. A different coil-arrangement parameter record is used for each image, which coil-arrangement parameter record is then associated with the image. Furthermore, the device assigns respectively one cost value to each of the plurality of images, which cost value corresponds to a measure of artifacts in the image. Finally, the device determines the radiation attenuation by the local coil from the arrangement-dependent radiation attenuation by the local coil and a coil-arrangement parameter record of one of the plurality of images by determining the optimum cost value of the cost values determined for the plurality of images.

The above-described device allows a quick and reliable determination of the radiation attenuation by the local coil in the tomography scanner without having to acquire additional raw radiation data.

According to one embodiment, the device is suitable for carrying out the above-described method and the embodiment thereof, and therefore also comprises the advantages described above in the context of the method.

Furthermore, according to at least one embodiment of the present invention, provision is made for a magnetic resonance-positron emission tomography system with a device as described above.

Moreover, at least one embodiment of the present invention comprises a computer program product, more particularly software, which can be loaded into a storage medium of a programmable control unit of a device for a magnetic resonance-positron emission tomography system. It is possible to carry out all above-described embodiments of the method according to the invention by using program means of this computer program product when the computer program product is carried out in the magnetic resonance-positron emission tomography system.

Finally, at least one embodiment of the present invention provides an electronically readable data medium, for example a CD or a DVD, on which electronically readable control information, more particularly software, is stored. When this control information is read by the data medium and stored in a magnetic resonance-positron emission tomography system, it is possible to carry out all embodiments according to at least one embodiment of the invention of the above-described method on the magnetic resonance-positron emission tomography system.

### BRIEF DESCRIPTION OF THE DRAWINGS

The present invention is explained below on the basis of example embodiments, with reference being made to the drawing.

FIG. 1 schematically shows a magnetic resonance-positron emission tomography system as per an embodiment of the present invention.

FIG. 2 shows a flowchart of an embodiment of the method according to the invention.

FIG. 3 shows positron emission tomography recordings in the case of an imprecisely determined arrangement of a local coil.

FIG. 4 shows the positron emission tomography recordings from FIG. 3 if the arrangement of the local coil is determined more precisely.

FIG. 5 shows a further positron emission tomography recording in the case of an imprecisely determined arrangement of a local coil.

FIG. 6 shows the positron emission tomography recordings from FIG. 5 if the arrangement of the local coil is determined more precisely.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

FIG. 1 shows a magnetic resonance-positron emission tomography system (MR-PET system) 1. The MR-PET system 1 comprises a tomography scanner 2, an examination table 3, a control unit 4 and an image-computer unit 5. The tomography scanner 2 has a tubular shape and is illustrated in a cut view in FIG. 1 along the longitudinal axis of the tomography scanner 2. The tomography scanner 2 comprises all devices that are required to acquire magnetic resonance recordings and positron emission tomography recordings. These additional devices of the tomography scanner 2 are not illustrated in FIG. 1 for reasons of clarity. The examination table 3 is arranged in the interior of the tubular tomography scanner 2. The control unit 4 is coupled to the tomography scanner 2 and is able to actuate the devices (not illustrated) in a suitable fashion for acquiring positron emission tomography recordings and magnetic resonance recordings in the tomography scanner 2. A person skilled in the art is aware of this and so, for this reason, this is not explained in any more detail.

The image-computer unit 5 is coupled to the control unit and is able to actuate the control unit 4 such that the control unit 4 provides raw data of a patient 6 arranged on the examination couch 3, selectively with the aid of a magnetic resonance recording method or a positron emission tomography recording method. The raw data provided by the control unit 4 are then processed in the image-calculation unit 5 in order to provide corresponding magnetic resonance recordings or positron emission tomography recordings for a user or medical practitioner of the MR-PET system. How appropriate image data is generated in the image-calculation unit 5 from the raw data of the control unit 4 is known to a person skilled in the art and so, for this reason, this is not explained in any more detail.

In order to generate a positron emission tomography image from raw positron emission tomography data, information relating to location-dependent attenuation of the examination region is required for absorption correction. This location-dependent attenuation is also referred to as an attenuation map or μ-map. In the case of MR-PET hybrid systems, this p-map is determined with the aid of a magnetic resonance recording of the examination object 6 (patient). In order to generate a p-map that is as precise as possible, it is often necessary to arrange one or more local coils 7 in the vicinity of the patient 6, in the examination region within the tomography scanner 2, in order to obtain an improved magnetic resonance recording. Although this provides a more precise p-map of the patient 6, the local coil 7 itself is not visible in the magnetic resonance recording, even though it can have a significant influence on the radiation data received during the positron emission tomography recording.

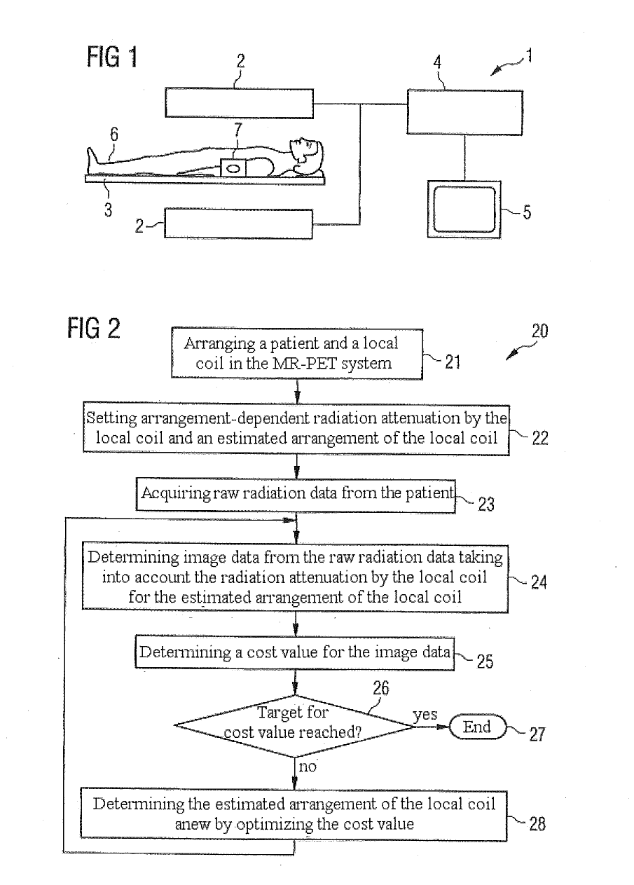

Accordingly, information relating to radiation attenuation in the region of the local coil 7, that is to say a μ-map of the local coil 7, is also required. In principle, the radiation attenuation by the local coil 7 may be determined from production information or separate measurements. However, in order to be able to take account of the radiation attenuation by the local coil 7 in a suitable fashion when a positron emission tomography recording is being generated, the radiation attenuation by the local coil 7 has to be included taking into account the position and alignment of the local coil 7 in the tomography scanner 2. However, it is not easy to determine the precise position of the local coil 7 within the tomography scanner 2 with the required accuracy, particularly in the case of local coils 7 that are arranged on a patient 6. It is for this reason that, as per one embodiment of the present invention, the method 20 illustrated in FIG. 2 is carried out in the MR-PET system 1, for example in the control unit 4 and the image-calculation unit 5.

The patient 6 and the local coil 7 are arranged in the MR-PET system 6 in step 21 of the method 20. In the following step 22, arrangement-dependent radiation attenuation by the local coil and an approximate arrangement of the local coil 7 in the tomography scanner 2 are set, for example in the image-calculation unit 5. By way of example, the arrangement-dependent radiation attenuation by the local coil 7 may be a function or a calculation prescription, which provides a p-map of the local coil 7 as a function of a coil-arrangement parameter record p. By way of example, the coil-arrangement parameter record p may comprise a position of the local coil 7 in x-, y-, and z-coordinates in the tomography scanner 2 and an alignment of the local coil 7, for example via alignment angles of the local coil 7 about x-, y-, and z-directions. Hence, the radiation attenuation μ_{coil} is a function of the coil-arrangement parameter record p.

Additionally, an estimate is made is step 22 of a coil arrangement p₀ of the local coil 7, i.e. the arrangement of the local coil 7 is, for example, measured approximately. Raw radiation data of the patient 6 is then acquired in step 23 with the aid of a positron emission tomography measurement. A positron emission tomography image B₀ is then determined in step 24 from the raw radiation data, taking into account the radiation attenuation μₚₐₜᵢₑₙₜ of the patient 6, which was previously determined from the magnetic resonance image, and the radiation attenuation μ_{coil}(p₀) by the local coil for the estimated arrangement p₀ of the local coil.

There are artifacts, in particular streak artifacts, in the positron emission tomography image B₀ as a result of the error in the estimation of the coil-arrangement parameter record p₀ because the estimated coil arrangement p₀ does not precisely correspond to the actual coil arrangement of the local coil 7. FIGS. 3 and 5 show positron emission tomography images with corresponding streak artifacts. In order to minimize these streak artifacts, the coil-arrangement parameter record p is varied in the method 20 until a coil-arrangement parameter record p is found in which there are fewer or no streak artifacts. To this end, a cost value K₀ is determined in step 25 for the previously determined positron emission tomography image. By way of example, the cost value K₀ is determined using an L1-norm-based total variation of the intensity values of the image. To this end, the deviation of the intensity of the pixel with respect to pixels in a predetermined neighborhood of this pixel is determined for each pixel, and the deviations determined thus are summed for the entire image:

$${K}_{0} = {\sum }_{x ∈ Ω} {\sum }_{Nb} \vert I ( x ) - I ( Nb ( x ) ) \vert ,$$

where x is a pixel in the image region Ω and Nb(x) is the neighborhood of x. I(x) specifies the intensity value of the pixel x. The total variation is a cost function, which provides piecewise constancy within the image with low costs and differences in the intensity of neighboring pixels with a high cost value. Intensity jumps for example between different tissue types are not overly penalized by the total variation; however, intensity variations within one tissue type are. Thus, the streak artifacts lead to an increase in the cost function. It goes without saying that, alternatively, it is possible to use other cost functions that prefer piecewise constancy. By way of example, it is possible to restrict the neighborhood to one direction, in which intensity jumps as a result of the streak artifacts are expected, for calculating the total variance or other suitable cost functions.

A check is carried out in step 26 as to whether a predetermined target, i.e. an abort criterion, for the cost value has been reached. Possible examples of reaching such a target are described below. If the target has not been reached, the estimated arrangement of the local coil 7 is determined anew in step 28, i.e. a new coil-arrangement parameter record p₁ is determined. By way of example, the new coil-arrangement parameter record p₁ can be generated by a slight variation in one or more parameters. As will be described below, this makes it possible to determine a new coil-arrangement parameter record by optimizing the cost value. However, a plurality of cost values for a plurality of positron emission tomography images with different coil-arrangement parameter records are required for this. In order to provide these starting from the first estimated coil arrangement, it is possible for the coil-arrangement parameter record to be varied randomly within prescribed variation boundaries.

The method 20 is continued in step 24 with the new coil-arrangement parameter record p₁, in which step a further positron emission tomography image B₁ is determined on the basis of the raw radiation data, taking into account the radiation attenuation μₚₐₜᵢₑₙₜ by the patient and the radiation attenuation μ_{coil}(p1) by the local coil 7 for the estimated arrangement p₁. A cost value K₁ for the image B₁ is then determined in step 25 as described above.

The corresponding cost values K are thus determined for a plurality of variations of coil-arrangement parameter records p. By way of example, in a simplified embodiment of the method 20, a predetermined number of positron emission tomography images and corresponding cost values for randomly selected coil-arrangement parameter records are determined, and the most expedient cost value is established. The coil-arrangement parameter record associated with the corresponding image and cost value is then used as radiation attenuation by the local coil 7.

However, as described in step 28 of the method 20, a new coil-arrangement parameter record may also be established by an optimization on the basis of the previously determined cost values. By way of example, a gradient descent method can be used for this purpose, which determines a gradient of the cost values over the coil-arrangement parameter record and establishes a new coil-arrangement parameter record by varying the coil-arrangement parameter record in the direction of the steepest falling gradient of the cost values. In this case, the target for the cost value (step 26) can be achieved when a local minimum was found for the cost value.

FIG. 3 shows positron emission tomography images that were determined from raw radiation data taking into account radiation attenuation by a local coil with a roughly estimated arrangement of the local coil. FIG. 4 shows the corresponding positron emission tomography images with the radiation attenuation by the local coil after the radiation attenuation was determined as per the method 20 illustrated in FIG. 2. While the streak artifacts are clearly visible in FIG. 3, only very few and significantly weaker streak artifacts can be identified in FIG. 4.

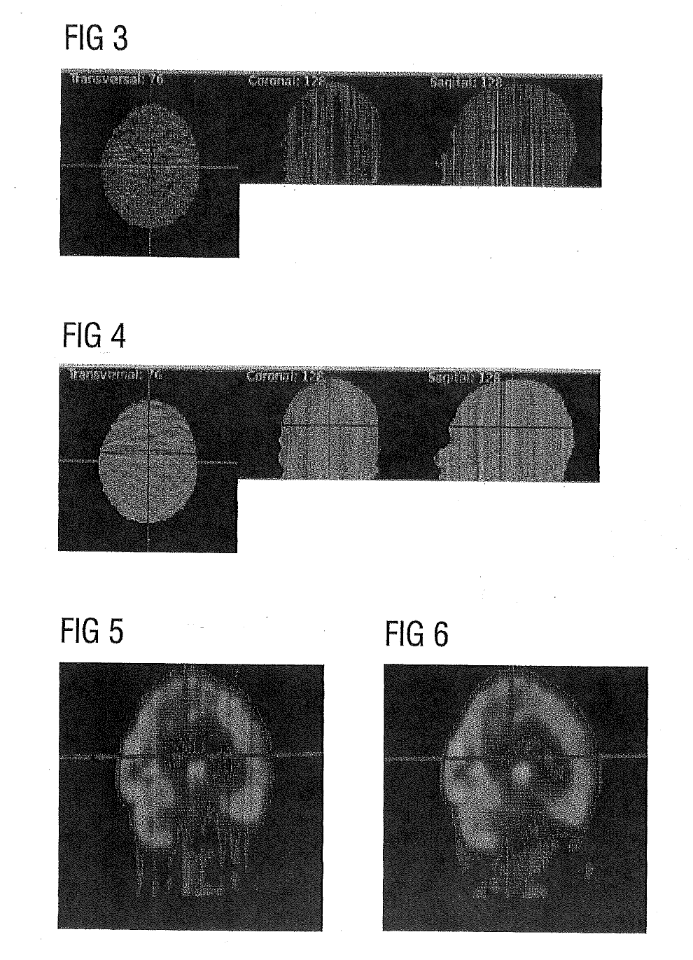

Like FIGS. 3 and 4, FIGS. 5 and 6 also show positron emission tomography images before and after applying the method illustrated in FIG. 2. Once again, streak artifacts are clearly visible in FIG. 5. The total variation of the image illustrated in FIG. 5, as determined in accordance with the above-described equation, has a value of approximately 420 000. By contrast, the total variance of the positron emission tomography image shown in FIG. 6 has a total-variation value of approximately 204 000.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, non-transitory computer readable medium and non-transitory computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a non-transitory computer readable medium and is adapted to perform any one of the aforementioned methods when run on a computer device (a device including a processor). Thus, the non-transitory storage medium or non-transitory computer readable medium, is adapted to store information and is adapted to interact with a data processing facility or computer device to execute the program of any of the above mentioned embodiments and/or to perform the method of any of the above mentioned embodiments.

The non-transitory computer readable medium or non-transitory storage medium may be a built-in medium installed inside a computer device main body or a removable non-transitory medium arranged so that it can be separated from the computer device main body. Examples of the built-in non-transitory medium include, but are not limited to, rewriteable non-volatile memories, such as ROMs and flash memories, and hard disks. Examples of the removable non-transitory medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

### LIST OF REFERENCE SIGNS

1 Magnetic resonance-positron emission tomography system
2 Tomography scanner
3 Examination table
4 Control unit
5 Image-computer unit
6 Patient
7 Local coil
20 Method
21-28 Step

What is claimed is:

1. A method for determining radiation attenuation by a local coil in a tomography scanner of a magnetic resonance-positron emission tomography system, the method comprising:
setting arrangement-dependent radiation attenuation by the local coil, arranged in the tomography scanner, wherein the arrangement-dependent radiation attenuation depends on a coil-arrangement parameter record, which describes an arrangement of the coil in the tomography scanner;
automatically acquiring raw radiation data of an examination object, including a positron emission source and arranged in the tomography scanner, with the aid of the positron emission tomography system;
automatically determining a plurality of images of the examination object from the raw radiation data, wherein each of the plurality of images is determined taking into account the arrangement-dependent radiation attenuation by the local coil for a coil-arrangement parameter record associated with a respective one of the plurality of images, with a different coil-arrangement parameter record being associated with each respective image;
automatically assigning a cost value to each of the plurality of images, wherein the respective cost value of a respective one of the plurality of images corresponds to a measure of artifacts in the respective image; and
automatically determining the radiation attenuation by the local coil from the arrangement-dependent radiation attenuation by the local coil and the coil-arrangement parameter record of one of the plurality of image by determining an optimized cost value of the cost values of the plurality of images.

2. The method as claimed in claim 1, wherein the coil-arrangement parameter record comprises a plurality of parameters, which describe a position and an alignment of the local coil.

3. The method as claimed in claim 1, wherein each respective cost value is formed from a plurality of cost-value components, which respectively evaluate one sub-region of the respective image, wherein a change in an intensity value of a pixel in the respective the image with respect to intensity values of respectively neighboring pixels is determined for one cost-value component.

4. The method as claimed in claim 1, wherein each respective cost value comprises a total variation of intensity values of pixels in the respective image, wherein a deviation of the intensity with respect to pixels within a neighborhood of the respective pixel is determined for each of the respective pixels.

5. The method as claimed in claim 1, wherein the coil-arrangement parameter record of the plurality of images is determined iteratively with the aid of an optimization method as a function of the cost values of previously determined images.

6. A device for a magnetic resonance-positron emission tomography system for determining radiation attenuation by a local coil in a tomography scanner of a magnetic resonance-positron emission tomography system, the device comprising:
a control unit to actuate a positron emission detector in the tomography scanner; and
an image-calculation unit to receive raw radiation data acquired by the positron emission detector and to reconstruct image data from the raw radiation data, wherein the device is embodied
to set arrangement-dependent radiation attenuation by the local coil arranged in the tomography scanner, wherein the arrangement-dependent radiation attenuation depends on a coil-arrangement parameter, which describes an arrangement of the local coil in the tomography scanner,
to acquire raw radiation data from an examination object, which includes a positron emission source, with the aid of the positron emission tomography system, while the local coil and the examination object are arranged in the tomography scanner,
to determine a plurality of images of the examination object from the raw radiation data, wherein each of the plurality of images is determined taking into account the arrangement-dependent radiation attenuation by the local coil for a coil-arrangement parameter record associated with respective the image, with a different coil-arrangement parameter record being associated with each of the plurality of images,
to assign respectively one cost value to each respective one of the plurality of images, wherein the respective cost value of a respective image corresponds to a measure of artifacts in the respective image, and
to determine the radiation attenuation by the local coil from the arrangement-dependent radiation attenuation by the local coil and the coil-arrangement parameter of one of the plurality of images by determining an optimized cost value of the cost values of the plurality of images.

7. The device as claimed in claim 6, wherein the device is embodied to carry out the method as claimed in 1.

8. A magnetic resonance-positron emission tomography system comprising a device as claimed in claim 6.

9. A computer program product, loadable directly into a storage medium of a programmable device of a magnetic resonance-positron emission tomography system, including program segments to carry out the method as claimed in claim 1 when the program is carried out in the device.

10. An electronically readable data medium including electronically readable control information stored thereon, embodied such that it carries out the method as claimed in claim 1 when the data medium is used in a programmable device of a magnetic resonance-positron emission tomography system.

11. A magnetic resonance-positron emission tomography system comprising a device as claimed in claim 7.

12. A non-transitory computer readable medium including program segments for, when executed on a computer device, causing the computer device to implement the method of claim 1.
